(19) United States
(12) Patent Application Publication
(10) Pub. No.: US 2014/0015150 A1
(43) Pub. Date: Jan. 16, 2014

(54) SEMICONDUCTOR DEVICE AND MANUFACTURING METHOD OF SAME

(71) Applicant: Teruhiko YATSUSHIRO, Toyota-shi (JP)

(72) Inventor: Teruhiko YATSUSHIRO, Toyota-shi (JP)

(73) Assignee: TOYOTA JIDOSHA KABUSHIKI KAISHA, Toyota-shi (JP)

(21) Appl. No.: 13/933,621

(22) Filed: Jul. 2, 2013

(30) Foreign Application Priority Data
Jul. 10, 2012 (JP) 2012-154720

(51) Int. Cl. H01L 23/544; H01L 21/02

(52) U.S. Cl. CPC H01L 23/544; H01L 21/02104
USPC 257/797; 438/761

(57) ABSTRACT

A semiconductor device manufacturing method includes forming a film on at least a portion of one surface of a semiconductor wafer, forming an alignment mark by providing a recessed portion on the film, and adhering a sheet to the one surface of the semiconductor wafer on which the alignment mark is formed.

### INCORPORATION BY REFERENCE

The disclosure of Japanese Patent Application No. 2012-154720 filed on Jul. 10, 2012 including the specification, drawings and abstract is incorporated herein by reference in its entirety.

### BACKGROUND OF THE INVENTION

1. Field of the Invention

The invention relates to a semiconductor device and a manufacturing method thereof.

2. Description of Related Art

In a semiconductor device manufacturing method, an alignment mark is formed on a surface of a semiconductor wafer, and the semiconductor wafer is aligned by detecting this alignment mark (see Japanese Patent Application Publication No. 2007-200953 (JP 2007-200953 A), for example).

When manufacturing a semiconductor device, a sheet is sometimes adhered to a surface of a semiconductor wafer. For example, when manufacturing a semiconductor device that is provided with a thin sheet-like semiconductor wafer, the sheet may be adhered to one surface of the semiconductor wafer (i.e., the surface on which the alignment mark is formed), and the other surface of the semiconductor wafer may be processed (e.g., polished, or a diffusion layer or an electrode or the like may be formed on it). In such a case, the sheet is adhered to the surface on which the alignment mark is fowled (i.e., one surface of the semiconductor wafer). Here, the alignment mark that is formed on the surface of the semiconductor wafer usually protrudes from the surface of the semiconductor wafer. Therefore, when the sheet is adhered to the surface of the semiconductor wafer, a gap is formed between the sheet, and the alignment mark and the semiconductor wafer surface. As a result, an air bubble may form between the sheet and the semiconductor wafer. If such an air bubble enters this gap, for example, the alignment mark may not be able to be properly detected.

### SUMMARY OF THE INVENTION

The invention thus provides a semiconductor device and manufacturing method thereof, in which an alignment mark is able to be properly detected.

A first aspect of the invention relates to a semiconductor device manufacturing method that includes forming a film on at least a portion of one surface of a semiconductor wafer, forming an alignment mark by providing a recessed portion on the film, and adhering a sheet to the one surface of the semiconductor wafer on which the alignment mark is formed.

A second aspect of the invention relates to a semiconductor device that includes a semiconductor substrate, a film that is provided on at least a portion of a surface of the semiconductor substrate and on which a recessed portion is provided, and a sheet that is provided on an upper surface of the film. A side of the recessed portion is surrounded by the film.

According to the aspects described above, the alignment mark is able to be properly detected.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein: FIG. 1 is a sectional view of a semiconductor wafer in a semiconductor device manufacturing method of the invention;

FIG. 2 is a sectional view of the semiconductor wafer in which a film is formed on a surface;

FIG. 3 is a sectional view of the semiconductor wafer in which an alignment mark is formed in the film (Le., a sectional view of the area near a portion where an alignment mark is formed);

FIG. 4 is a plan view of the semiconductor wafer in which the alignment mark is formed in the film (i.e., a plan view of the area near the portion where the alignment mark is formed);

FIG. 5 is a sectional view of the semiconductor wafer in which protective tape is adhered onto the film in which the alignment mark is formed;

FIG. 6 is a plan view of the semiconductor wafer in which the protective tape is adhered onto the film in which the alignment mark is formed;

FIG. 7 is a view showing the manner in which the semiconductor wafer and a photomask are positioned in a process for exposing a back surface of the semiconductor wafer;

FIG. 8 is a sectional view showing a state in which protective tape is adhered onto a surface of a semiconductor wafer on which a protruding alignment mark is formed according to related art; and

FIG. 9 is a plan view of the state in which the protective tape is adhered onto the surface of the semiconductor wafer on which the protruding alignment mark is formed according to the related art.

### DETAILED DESCRIPTION OF EMBODIMENTS

Example embodiments of the semiconductor device manufacturing method of the invention will now be described, FIG. 1 is a sectional view of a semiconductor wafer 2 in the semiconductor device manufacturing method of the invention. Although not shown, a semiconductor element structure of a diffusion layer ox an insulating film or the like is formed on a front surface 2a side of the semiconductor wafer 2. The semiconductor element structure on the front surface 2a side may be formed by a well-known method, so a description of this forming method will be omitted. At the stage shown in FIG. 1, the semiconductor element structure is not formed on a back surface 2b side of the semiconductor wafer 2. The front surface 2a is one example of one surface of the semiconductor wafer, and the back surface 2b is one example of the other surface of the semiconductor wafer. In this example embodiment, the semiconductor device is manufactured by performing a film forming step, an alignment mark forming step, a sheet adhering step, and a back surface processing step on the semiconductor wafer 2 shown in FIG. 1.

### [Film Forming Step]

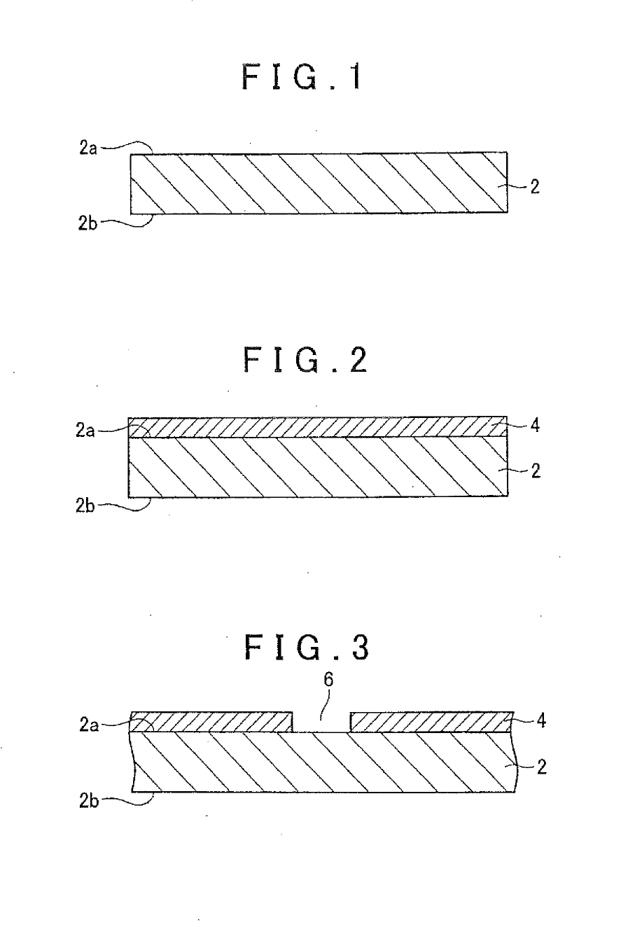

In the film forming step, an Al film 4 is formed on at least a portion of the front surface 2a of the semiconductor wafer 2. A sputtering method, for example, may be used to form this Al film 4. More specifically, argon ionized in plasma is accelerated by an electric field and collided with an Al sheet. Al atoms that are sent flying by the impact upon collision adhere on the front surface 2a of the semiconductor wafer 2, thereby forming the Al film 4 as shown in FIG. 2. The Al film 4 may be a film that covers the entire surface of the front surface 2a of the semiconductor wafer 2, or it may be a film that covers only a portion of the front surface 2a of the semiconductor wafer 2. The film formed on the front surface 2a of the semiconductor wafer 2 (i.e., the film used to form the alignment mark) is not limited to an Al film. For example, the film may also be a film that contains Cu, or another metal film, or a film that contains Si. Also, a method other than a sputtering method may be used to form the film. For example, the film may also be formed by a vapor deposition method or plating.

### [Alignment Mark Forming Step]

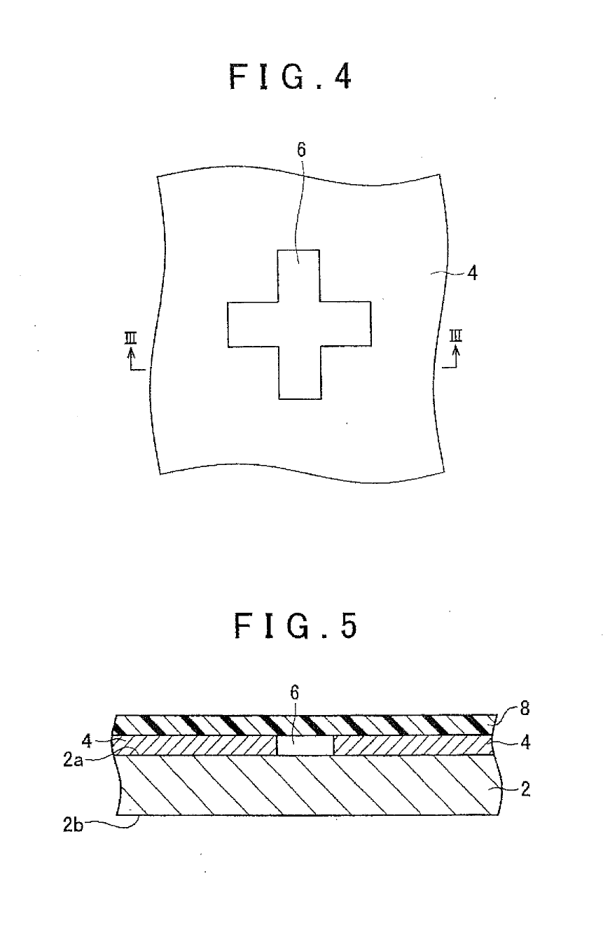

In the alignment mark forming step, an alignment mark 6 is formed by providing a recessed portion on the Al film 4. That is, the alignment mark is formed as a pattern of a recessed portion provided on the Al film 4. More specifically, a mask is formed on the front surface of the Al film 4 by photolithography, and etching is applied to the Al film. 4 via the mask. When etching is applied to the Al film 4, a recessed portion following the pattern is formed on the Al film 4 as shown in FIG. 3. This recessed portion, or part of this recessed portion, is the alignment mark 6. The alignment mark 6 may be a pattern in which the sides of the formed recessed portion are surrounded by the Al film 4. Accordingly, the likelihood of a bubble entering the recessed portion from the side of the recessed portion when protective tape 8 is adhered from above the alignment mark 6, or after the protective tape 8 is adhered, is able to be reduced. In this example embodiment, a cross-shaped recessed portion such as that shown in FIG. 4 is the alignment mark 6. However, the shape of the alignment mark is not limited to being cross-shaped. Any appropriate shape may be used. Also, FIG. 3 is a sectional view of the semiconductor wafer 2 taken along line III-III in FIG. 4.

### [Sheet Adhering Step]

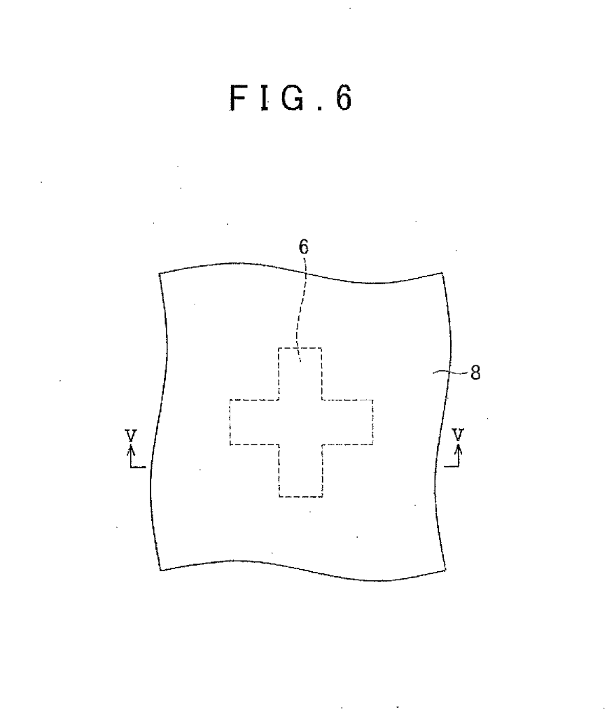

In the sheet adhering step, the protective tape 8 is adhered to the front surface 2a of the semiconductor wafer 2 on which the alignment mark 6 is formed. The protective tape S is one example of the sheet. Tape that is highly rigid and has high adhesive strength may he used for the protective tape 8, so that the protective tape 8 will not peel off in the manufacturing steps that follow. FIG. 5 is a sectional view of the semiconductor wafer 2 in which the protective tape 8 has been adhered onto the Al film 4 on which the alignment mark 6 has been formed. As shown in FIG. 5, the protective tape 8 may be adhered smoothly on the Al film 4 so that it does not enter the recessed portion that forms the alignment mark 6. As a result, a space that is surrounded by the front surface 2a of the semiconductor wafer 2, the Al film 4, and the protective tape 8 is formed in the alignment mark 6. Consequently, the likelihood that the alignment mark 6 will fail to be recognized due to distortion of the protective tape 8 (i.e., due to the protective tape 8 becoming misshapen) or the like is able to be reduced. FIG. 6 is a plan view of the semiconductor wafer 2 in FIG. 5. The protective tape 8 may also be transparent. Thus, even when the protective tape 8 is adhered onto the Al film 4, the cross-shaped alignment mark 6 is able be recognized through the protective tape 8. The protective tape 8 is adhered for the purpose of preventing scrap produced during the processing step from adhering to the front surface 2a when the back surface 2b of the semiconductor wafer 2 is processed. However, the purpose of affixing the protective tape 8 is not limited to this. The protective tape 8 may also be adhered in order to prevent grinding dust that is produced when the hack surface 2b of the semiconductor wafer 2 is ground from adhering to the front surface 2a when the back surface 2b is ground. Also, the protective tape 8 may also be adhered to prevent the semiconductor wafer 2 that has become thin from grinding from breaking. FIG. 5 is a sectional view of the semiconductor wafer 2 taken along line V-V in FIG. 6.

### [Back Surface Processing Step]

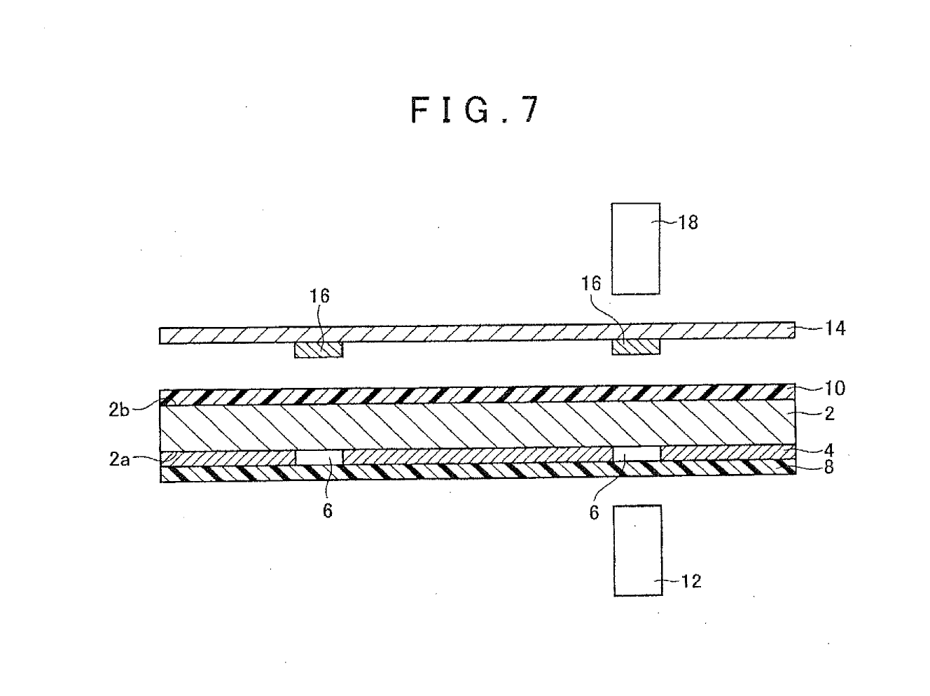

In the back surface processing step, the back surface 2b of the semiconductor wafer 2 is processed based on the position of the alignment mark 6. FIG. 7 is a view showing the manner in which the semiconductor wafer 2 and a photomask 14 are positioned in an exposure process performed in the processing step of the back surface 2b. One example of the back surface processing step will be described with reference to FIG. 7. First, a photoresist 10 is applied to the back surface 2b of the semiconductor wafer 2. Next, the semiconductor wafer 2 and the photomask 14 are positioned, This positioning is performed by positioning the alignment mark 6 formed on the front surface 2a of the semiconductor wafer 2, and an alignment mark 16 formed on the photomask 14. More specifically, first, the semiconductor wafer 2 is placed on a stage, not shown, with the back surface 2b facing up. Then, an alignment camera 12 that is arranged on the front surface 2a side of the semiconductor wafer 2 performs image recognition and recognizes the alignment mark 6 through the protective tape 8. The alignment camera 12 then checks the obtained image data against a master pattern stored in the alignment camera 12 beforehand, calculates an amount of offset from a reference point (such as the center of the master pattern), and moves the stage based on the calculated offset amount In this way, the semiconductor wafer 2 is set in a predetermined position. The method for setting the photomask 14 is basically the same as this method, That is, an alignment camera 18 arranged on the side opposite the side of the photomask 14 on which the semiconductor wafer 2 is arranged performs image recognition and recognizes the alignment mark 16 formed on the photomask 14. The alignment camera 18 then checks the obtained image data against a master pattern stored in the alignment camera 18 beforehand, calculates an amount of offset, and moves the photomask 14 based on the calculated offset amount. The shapes and sizes of the alignment mark 6 and the alignment mark 16 may be the same or different. Continuing on, an exposure device, not shown, irradiates light on the photoresist 10 through the photomask 14, and transfers the pattern of the photomask 14 onto the photoresist 10. Then the photoresist 10 is developed and a mask is formed. This mask is then used to form a diffusion layer or the like. Once the processing of the back surface 2b is complete, the protective tape 8 is peeled off. The protective tape 8 is peeled off with peeling tape, not shown. Once the protective tape 8 is peeled off, dicing tape is affixed to the semiconductor wafer 2. Then, the semiconductor wafer 2 is diced, and the semiconductor wafer 2 is divided into semiconductor devices of a predetermined chip size. With this, the semiconductor device is complete.

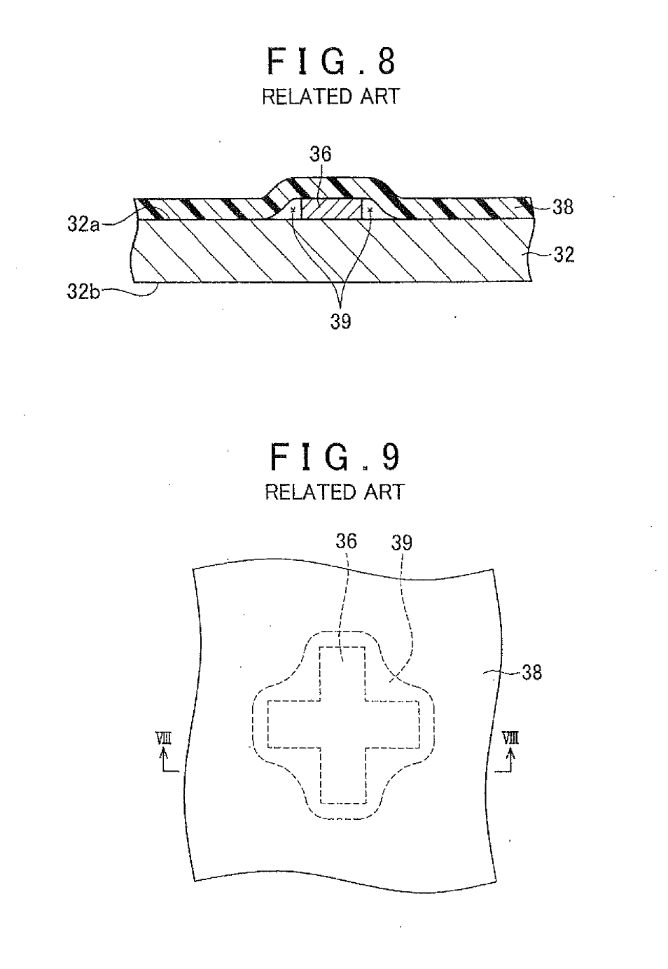

The advantages of the semiconductor device manufacturing method of this example embodiment will now be described in comparison to the related art. FIG. 8 is a sectional view of a related semiconductor wafer 32, and FIG. 9 is a plan view of the related semiconductor wafer 32. As shown in FIG. 8, a related alignment mark 36 is formed by a surface that protrudes from a front surface 32a of the semiconductor wafer 32. In other words, a protruding portion or a part of the protruding portion, of a recessed portion and a protruding portion formed by hulling a pattern by photolithography or the like on a film formed on the semiconductor wafer 32, is used as the alignment mark 36. In this ease, when adhering protective tape 38 to the front surface 32a on which the alignment mark 36 is formed, a gap is formed between the protective tape 38 and the semiconductor wafer 32, and a bubble 29 may enter this gap. If this happens, the outline of the alignment mark 36 becomes vague due to the gap near the alignment mark 36, as shown in FIG. 9. For example, the shape (the end portion) of the gap may be falsely recognized as the pattern of the alignment mark 36. Therefore, image recognition of the alignment mark 36 by the alignment camera may be difficult, and as a result, the alignment mark 36 may be misdetected. In this case, the semiconductor wafer 32 will be set based on the position of the misdetected alignment mark 36. On the other hand, with the semiconductor device manufacturing method according to this example embodiment, the recessed portion or a part of the recessed portion, of the recessed portion and the protruding portion formed by forming the pattern on the Al film 4 formed on the semiconductor wafer 2, is used as the alignment mark 6, as shown in FIG. 5. In this case, when adhering the protective tape 8 to the front surface 2a of the semiconductor wafer 2 (i.e., the Al film 4), the protective tape 8 closely adheres to the area near the alignment mark 6. Therefore, a bubble is inhibited from getting inside or near the alignment mark 6. Accordingly, the outline of the alignment mark 6 is sharper, as shown in FIG. 6, so the alignment camera 12 is able to more accurately detect the alignment mark 6. As a result, the semiconductor wafer 2 is able to be properly set in the predetermined position. Also, the positioning process will not be disrupted due to the alignment mark 6 being unable to be recognized by image recognition, so a decrease in production efficiency is able to be inhibited.

Heretofore, example embodiments of the technology described in this specification are described in detail, but the invention is not limited to these. To the contrary, the semiconductor device manufacturing method described in this specification also includes variations and modifications of the example embodiments described above. For example, in the example embodiments described above, the alignment mark 6 is formed by photolithography, but the alignment mark may also be formed using another method. Also, the number of locations where the alignment mark 6 and the alignment mark 16 are formed is not limited to two. For example, a plurality of the alignment marks 6 and the alignment marks 16 may also be formed on the front, rear, left, and right of the semiconductor wafer 2 and the photomask 14. Also, in the example embodiments described above, the photoresist 10 is applied to the back surface 2b of the semiconductor wafer 2, but the film may also be formed before the photoresist 10 is applied.

Heretofore, specific examples of the invention have been described in detail, but these are merely examples, and the invention is not limited to these examples. The invention also includes various modifications of the specific examples described above. Also, the technical elements illustrated in the example embodiments and the drawings display technical utility both alone and in various combinations. Further, the technology illustrated in the example embodiments and the drawings simultaneously achieves a plurality of objects, and has technical utility by simply achieving one of these objects.

What is claimed is:

1. A semiconductor device manufacturing method comprising:
forming a film on at least a portion of one surface of a semiconductor wafer;
forming an alignment mark by providing a recessed portion on the film; and
adhering a sheet to the one surface of the semiconductor wafer on which the alignment mark is formed.

2. The semiconductor device manufacturing method according to claim 1, further comprising processing the other surface of the semiconductor wafer, based on a position of the alignment mark detected through the sheet.

3. The semiconductor device manufacturing method according to claim 1, wherein when adhering the sheet, the sheet is adhered so as not to enter the recessed portion.

4. A semiconductor device comprising:
a semiconductor substrate;
a film that is provided on at least a portion of a surface of the semiconductor substrate and on which a recessed portion is provided; and
a sheet that is provided on an upper surface of the film,
wherein a side of the recessed portion is surrounded by the film.
